(19) United States
(12) Patent Application Publication
(10) Pub. No.: US 2026/0318511 A1
(43) Pub. Date: Oct. 15, 2026

(54) LED MODULE

(71) Applicant: SIGNIFY HOLDING B.V., EINDHOVEN (NL)

(72) Inventors: PETER HENRI BANCKEN, HEEZE (NL); WALDEMAR MARCIN SUREK, WROCLAW (PL); SEBASTIAN MARCIN SZCZECH, PILA (PL); FRITZ HELMUT ZAHN, GELDROP (NL)

(21) Appl. No.: 19/481,974

(22) PCT Filed: Apr. 26, 2024
(86) PCT No.: PCT/EP2024/061656

§ 371 Date: Nov. 6, 2025

(30) Foreign Application Priority Data
May 8, 2023 (EP) 23171975.8

(51) Int. Cl. F21V 19/00; F21S 4/22; F21V 21/005; F21V 23/06; F21Y 105/16; F21Y 115/10; H05K 1/11; H05K 1/14

(52) U.S. Cl. CPC F21V 19/0045; F21S 4/22; F21V 21/005; F21V 23/06; H05K 1/117; H05K 1/142; H05K 1/148; F21Y 2105/16; F21Y 2115/10; H05K 2201/10106

(57) ABSTRACT

A LED module comprises a printed circuit board, PCB, on which PCB at least one light emitting diode, LED, is arranged. The PCB comprises a first mechanical and electrical interface arranged at a first end of the PCB and a second mechanical and electrical interface arranged at a second end of the PCB. The first mechanical and electrical interface comprises a convex edge of the first end of the PCB having a first curvature radius. The second mechanical and electrical interface comprises, at the second end of the PCB, a concave edge having the first curvature radius. The concave edge is configured to receive a convex edge of a first mechanical and electrical interface of another LED module. The at least one LED is arranged in electrical connection with the first mechanical and electrical interface and in electrical connection with the second mechanical and electrical interface.

### FIELD OF THE INVENTION

The present invention generally relates to light emitting modules. More specifically, the present invention is related to a light emitting diode (LED) module comprising mechanical and electrical interfaces for connection with another LED module, a system comprising such modules and a luminaire comprising such a system.

### BACKGROUND OF THE INVENTION

It has been found that there exists a desire to provide luminaires that are configured with curved shapes. Current luminaires are typically configured with high-efficient LED modules as light sources. However, high-efficient LED modules are devices that are manufactured using rigid printed circuit board (PCB) material and they are usually designed in the form of straight modules. As a consequence, such LED modules are rigid and therefore more or less impossible to bend in-plane in order to realize a curved shape.

Needless to say, curved shapes can be realized with pre-shaped curved PCB's. But an inherent drawback of pre-shaped PCB's is that for the realization of a plurality of different curved shapes, e.g. circular luminaires having different diameters, a significant set of different LED modules is needed, each having a specific curved shape to fit a specific curved luminaire.

NL201687B1 discloses an illumination device comprising a circuit board assembly including a first and second circuit board in a formfitting, interlocking relationship.

JP2010262744A discloses a connection type luminaire capable of connecting a plurality of luminaires.

### SUMMARY OF THE INVENTION

In view of the drawbacks associated with known LED modules as discussed above, it is of interest to provide a LED module that is capable of fit any curve shaped luminaire.

This and other objects are achieved in a first aspect by providing a LED module having the features of the appended claim 1. Preferred embodiments are defined in the appended dependent claims.

Hence, according to the present invention, there is provided a LED module comprising a PCB, e.g. a rigid PCB, on which PCB at least one LED is arranged. The PCB comprises a first mechanical and electrical interface arranged at a first end of the PCB and a second mechanical and electrical interface arranged at a second end of the PCB. The first mechanical and electrical interface comprises a convex edge of the first end of the PCB having a first curvature radius. The second mechanical and electrical interface comprises, at the second end of the PCB, a concave edge having (a second curvature being slightly smaller than or having at the most) the first curvature radius. The concave edge is configured to receive a convex edge of a first mechanical and electrical interface of another LED module. The at least one LED is arranged in electrical connection with the first mechanical and electrical interface and in electrical connection with the second mechanical and electrical interface. For the convex edge of a first LED module to be easily and suitably receivable by the concave edge of the neighboring second LED module, the first curvature and the second curvature preferably are essentially concentrically arranged to enable smooth and mutual rotation without (significant) deformation of the first and/or second LED module. The first end of the PCB and the second end of the PCB may be opposite ends of the PCB. However, other configurations in terms of angular relationship between the two ends of the PCB are feasible, as long as the interfaces allow connection between adjoining LED modules.

The first mechanical and electrical interface may comprise at least a first connection strip extending from the first end of the PCB and the second mechanical and electrical interface may comprise an arc-shaped slot in the PCB. The arc-shaped slot is then concentric with the concave edge of the second end of the PCB and the arc-shaped slot has a curvature radius that is greater than the first curvature radius and configured to receive at least a first connection strip of said first mechanical and electrical interface of said another LED module.

That is, such a LED module enables configuration of a luminaire having a curved shape. Specifically, two or more such LED modules may be connected via the first mechanical and electrical interface of a first LED module and a second mechanical and electrical interface of a second LED module. The convex shape of the first mechanical and electrical interface and the concave shape of the second mechanical and electrical interface, including the concave edge and the arc-shaped concentric concave slot receiving a connection strip of the first mechanical and electrical interface of the first LED module, allow the first and second LED modules to be arranged at an adjustable angle in relation to each other while maintaining electrical connection between the LED modules.

The at least first connection strip may comprises a resilient bulge that fits into the arc-shaped slot and thereby provide a firm mechanical connection between the LED module and said another LED module. such a bulged strip may be configured, for example in the form of a (thin) metal sheet material such that it provides a firm mechanical connection between the LED module and said another LED module. The bulge may be more or less according to a “flat bottom U”-shape, however, other shapes may be used including “U”-shaped and “O”-shaped.

The first and second mechanical and electrical interfaces of the LED module may be configured in various ways in order to enable various configurations of electrical and mechanical connection between a first and a second LED module.

In a first module configuration, the at least first connection strip is an electrically conducting connection strip and the arc-shaped slot comprises at least a first electrical contact surface. In such a configuration, the arc-shaped slot is configured to receive said at least first electrically conducting connection strip of said another LED module such that said at least first electrical contact surface connect with said at least first electrically conducting connection strip.

That is, in the first module configuration of a first and a second connected LED module, the connection strip of the first LED module and the slot of the second LED module provide a dual electrical and mechanical connection between the first and the second LED module while the convex edge of the first LED module and the concave edge of the second LED module provide only a mechanical connection between the first and the second LED module.

In a second module configuration, the convex edge of the first end of the PCB comprises at least a first convex electrical contact surface and the concave edge of the second end of the PCB comprises at least a first concave electrical contact surface. In such a configuration, said at least first convex electrical contact surface is configured to electrically connect with said at least first concave electrical contact surface of said another LED module.

That is, in the second module configuration of a first and a second connected LED module, the connection strip of the first LED module and the slot of the second LED module provide only a mechanical connection between the first and the second LED module while the convex edge of the first LED module and the concave edge of the second LED module provide a dual electrical and mechanical connection between the first and the second LED module.

In a third module configuration, the convex edge of the first end of the PCB comprises a first convex electrical contact surface and the concave edge of the second end of the PCB comprises a first concave electrical contact surface. In such a configuration, said first convex electrical contact surface is configured to electrically connect with said first concave electrical contact surface of said another LED module. Moreover, in such a configuration, the at least first connection strip is an electrically conducting connection strip and the arc-shaped slot comprises a first electrical contact surface and the arc-shaped slot is configured to receive said first electrically conducting connection strip of said another LED module such that said first electrical contact surface connect with said first electrically conducting connection strip.

That is, in the third module configuration of a first and a second connected LED module, the connection strip of the first LED module and the slot of the second LED module provide a dual electrical and mechanical connection between the first and the second LED module and the convex edge of the first LED module and the concave edge of the second LED module also provide a dual electrical and mechanical connection between the first and the second LED module.

The arc-shaped slot may be in the form of a through-going slot in the PCB and the LED module may comprise a second connection strip extending from the first end of the PCB. In such a case, the first connection strip may be arranged on a front side of the PCB and the second connection strip may be arranged on a back side of the PCB and the arc-shaped slot is thus configured to receive the second connection strip of said another LED module.

That is, such a LED module enables a firm mechanical connection between connected LED modules due to the fact that that the connection strips are arranged on opposite sides of the PCB and thereby provide a grappling claw function.

Such a LED module may be configured such that the second connection strip is an electrically conducting connection strip and the arc-shaped slot comprises a second electrical contact surface. The first and the second electrical contact surface in such a LED module may be arranged electrically isolated from each other along the length of the arc-shaped slot and at least on one inner side wall of the arc-shaped slot. The arc-shaped slot is thus configured to receive the first electrically conducting connection strip and the second electrically conducting connection strip such that the first and second electrical contact surfaces connect with the first and the second electrically conducting connection strips, respectively, of said another LED module.

That is, in such configurations the LED module comprises two connection strips extending from the first end of the PCB and the arc-shaped slot comprises two electrical contact surfaces that enable an electrical parallel connection between connected LED modules where convex edges and concave edges provide the mechanical connection between the LED modules.

Moreover, in such configurations, the inner side of the arc-shaped slot may comprise a first inner side wall opposite a second inner side wall, wherein the first electrical contact surface is arranged only on the first inner side wall along the length of the arc-shaped slot, and the second electrical contact surface is arranged only on the second inner side wall along the length of the arc-shaped slot. Such a configuration minimizes the risk of electric shortening between electrically conducting connection strip and/or the electrical contact surfaces.

It will be appreciated that LED modules having the first and the second type of module configuration, as summarized above, may electrically connect with each other via one connection between an electrically conducting connection strip and an electrical contact surface or via two connections between two electrically conducting connection strips and two electrical contact surfaces. Such a one-connection configuration may be considered as a serial coupling configuration and thus allowing a high voltage supply, whereas a two-connection configuration may be considered as a parallel coupling configuration and thus being suited for a low voltage supply.

In configurations of a LED module without connection strips in the first mechanical and electrical interface and without an arc-shaped slot in the second mechanical and electrical interface, the convex edge of the first end of the PCB may comprise a first convex electrical contact surface and the concave edge of the second end of the PCB may comprise a first concave electrical contact surface. In these configurations, the first convex electrical contact surface is configured to electrically connect with the first concave electrical contact surface of said another LED module.

Such a LED module may be further configured such that the convex edge of the first end of the PCB further comprises a second convex electrical contact surface and the concave edge of the second end of the PCB further comprises a second concave electrical contact surface. In these configurations, the second convex electrical contact surface is configured to electrically connect with the second concave electrical contact surface of said another LED module.

That is, such LED modules may be seen as being configured as pieces of a jigsaw puzzle, where a male, i.e. convex, edge fits into a concave, i.e. female, edge. In order to further secure mechanical contact between contact surfaces on the convex and concave edges, the convex edge of the first end of the PCB may comprise a cut-out slot. Such a cut-out slot provides the convex edge with an amount of mechanical resilience in the plane of the PCB. By configuring the concave edge such that the curvature radius of the concave edge is marginally smaller than the first curvature radius of the convex edge, a firm mechanical connection between the resilient convex edge and the concave edge of another LED module will be ensured.

The objects discussed above are achieved in a second aspect by providing a system comprising a plurality of LED modules as summarized above.

For example, in a two-LED module system, a first mechanical and electrical interface of a first LED module of the plurality of LED modules may be connected with a second mechanical and electrical interface of a second LED module of the plurality of LED modules such that a convex edge of the first mechanical and electrical interface of the first LED module abuts a concave edge of the second mechanical and electrical interface of the second LED module. In such a system at least a first connection strip of the first mechanical and electrical interface of the first LED module is received in an arc-shaped slot of the second mechanical and electrical interface of the second LED module.

A three-LED module system is obtained by adding a third LED module to such a two-LED module system. Hence, a first mechanical and electrical interface of a third LED module of the plurality of LED modules may be connected with a second mechanical and electrical interface of the first LED module such that a convex edge of the first mechanical and electrical interface of the third LED module abuts a concave edge of the second mechanical and electrical interface of the first LED module, and at least a first connection strip of the first mechanical and electrical interface of the third LED module is received in an arc-shaped slot of the second mechanical and electrical interface of the first LED module.

In a system having an arbitrary number of LED modules, a first mechanical and electrical interface of a LED module n of the plurality of LED modules may be connected with a second mechanical and electrical interface of a LED module n+1 such that
a convex edge of the first mechanical and electrical interface of the LED module n abuts a concave edge of the second mechanical and electrical interface of the LED module n+1 and at least a first connection strip of the first mechanical and electrical interface of the LED module n is received in an arc-shaped slot of the second mechanical and electrical interface of the n+1 LED module. In such a system, a second mechanical and electrical interface of a LED module n of the plurality of LED modules may be connected with a first mechanical and electrical interface of the LED module n−1 such that a concave edge of the second mechanical and electrical interface of the LED module n abuts a convex edge of the first mechanical and electrical interface of the LED module n−1, and an arc-shaped slot of the second mechanical and electrical interface of the LED module n receives at least a first connection strip of the first mechanical and electrical interface of the LED module n−1.

Similarly, in a system having an arbitrary number of LED modules without connection strips in the first mechanical and electrical interface and without an arc-shaped slot in the second mechanical and electrical interface, a first mechanical and electrical interface of a LED module n of the plurality of LED modules may be connected with a second mechanical and electrical interface of a LED module n+1 such that a convex edge of the first mechanical and electrical interface of the LED module n abuts a concave edge of the second mechanical and electrical interface of the LED module n+1. In such a system, a second mechanical and electrical interface of a LED module n of the plurality of LED modules may be connected with a first mechanical and electrical interface of the LED module n−1 such that a concave edge of the second mechanical and electrical interface of the LED module n abuts a convex edge of the first mechanical and electrical interface of the LED module n−1.

The objects discussed above are achieved in a third aspect by providing a luminaire comprising any system as summarized above.

### BRIEF DESCRIPTION OF THE DRAWINGS

This and other aspects of the present invention will now be described in more detail, with reference to the appended drawings showing embodiment(s) of the invention.

FIG. 1a schematically illustrates a top view of a LED module,

FIG. 1b schematically illustrates a cross section A-A of the LED module in FIG. 1a,

FIG. 1c schematically illustrates a cross section B-B of the LED module in FIG. 1a,

FIG. 1d schematically illustrates a side view C-C of the LED module in FIG. 1a,

FIG. 1e schematically illustrates a side view D-D of the LED module in FIG.

1a,

FIG. 2a schematically illustrates a top view of a LED module,

FIG. 2b schematically illustrates a cross section E-E of the LED module in

FIG. 2a,

FIG. 2c schematically illustrates a cross section F-F of the LED module in FIG. 2a,

FIG. 2d schematically illustrates a side view G-G of the LED module in FIG. 2a,

FIG. 3 schematically illustrates a top view of a system of LED modules, and

FIG. 4 schematically illustrates a luminaire comprising a system of LED modules.

### DETAILED DESCRIPTION

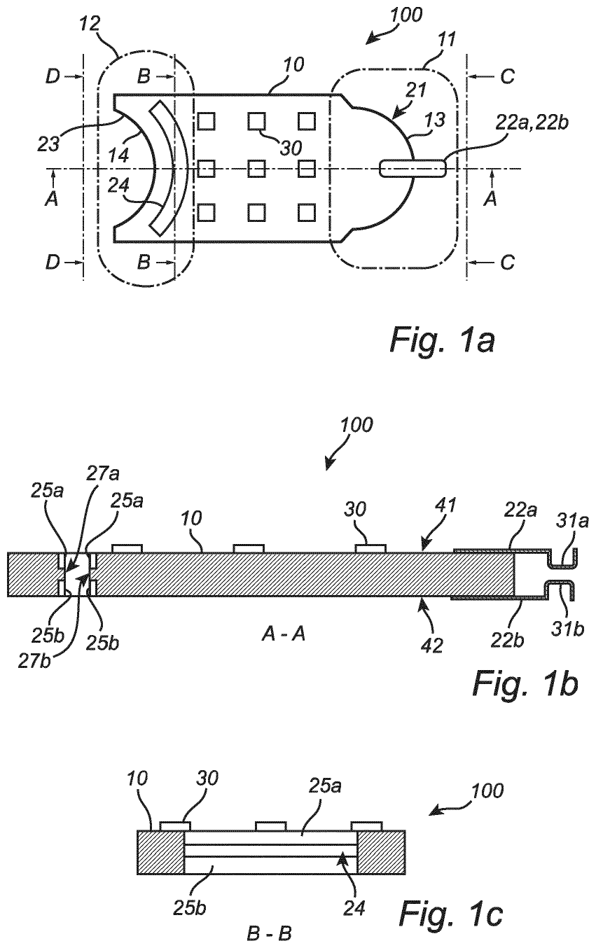

As illustrated in FIG. 1a-e, an embodiment of a LED module 100 comprises a printed circuit board (PCB) 10 on which PCB 10 at least one LED 30 is arranged. The PCB 10 comprises a first mechanical and electrical interface 11 arranged at a first end 13 of the PCB 10 and a second mechanical and electrical interface 12 arranged at a second end 14 of the PCB 10. As exemplified in FIGS. 1a-e, the first end 13 of the PCB 10 and the second end 14 of the PCB 10 may be opposite ends of the PCB 10. However, other relationships may be realized where ends and interfaces of the PCB have other angular relationships.

The first mechanical and electrical interface 11 comprises a convex edge 21 of the first end 13 of the PCB 10 and the convex edge 21 has a first curvature radius. Further, in the embodiment illustrated in FIGS. 1a-e, the first mechanical and electrical interface 11 comprises at least a first connection strip 22a extending from the first end 13 of the PCB 10.

The second mechanical and electrical interface 12 comprises, at the second end 14 of the PCB 10, a concave edge 23 that has the first curvature radius, i.e. the same curvature radius as the curvature radius of the convex edge 21 at the first end 13 of the PCB. The concave edge 23 is configured to receive a convex edge 21 of a first mechanical and electrical interface 11 of another LED module 100. Further, in the embodiment illustrated in FIGS. 1a-e, the second mechanical and electrical interface 12 comprises an arc-shaped slot 24 in the PCB 10 that is concentric with the concave edge 23 of the second end 14 of the PCB 10. The arc-shaped slot 24 has a curvature radius that is greater than the first curvature radius and configured to receive at least a first connection strip 22a of said first mechanical and electrical interface 11 of said another LED module 100.

The convex edge 21 of the first mechanical and electrical interface 11 of the LED module 100 and the concave edge 23 of the second mechanical and electrical interface 12 of another LED module 100 have concentrically arranged curvatures in order to enable smooth mutual rotation of between LED modules, without risking any deformation of any of the edges 21, 23.

The at least one LED 30 is arranged in electrical connection with the first mechanical and electrical interface 11 and in electrical connection with the second mechanical and electrical interface 12. Such electrical connections between the at least one LED 30 and the interfaces 11, 12 may be realized via connection paths on the surface of the PCB 10 as well as via paths within the PCB 10.

FIG. 1b illustrates that the at least first connection strip 22a comprises a resilient bulge 31a that fits into the arc-shaped slot 24. That is, such a bulged strip may be configured, e.g., in the form of a thin metal sheet material such that it provides a firm mechanical connection between the LED module and said another LED module.

As mentioned above, the arc-shaped slot 24 in the PCB 10 is concentric with the concave edge 23 of the second mechanical and electrical interface 12. This means that rotation between the LED module 100 and another LED module 100 will result in that the bulge 31a will follow a curve that is concentric with the curvature of the arc-shaped slot 24 and thereby enable smooth mutual rotation of between LED modules, without risking any deformation of any of the bulge 31a and the arc-shaped slot 24.

As exemplified in FIG. 1b, the bulge 31a is more or less a “flat bottom U”-shape, however other shapes may be used including “U”-shaped and “O”-shaped.

As mentioned above, the first and second mechanical and electrical interfaces 11, 12 of the LED module 100 may have different configurations in terms of electrical and mechanical connection between a first and a second LED module.

In a first type of configuration, the at least first connection strip 22a may be an electrically conducting connection strip and the arc-shaped slot 24 may comprise at least a first electrical contact surface 25a. In such a configuration, the arc-shaped slot 24 is configured to receive the at least first electrically conducting connection strip 22a of said another LED module 100 such that said at least first electrical contact surface 25a connect with said at least first electrically conducting connection strip 22a. As exemplified in FIG. 1b, the first electrical contact surface 25a may be arranged along the length of the arc-shaped slot 24 and at least on one inner side wall 27a, 27b of the arc-shaped slot 24.

In a second type of configuration, the convex edge 21 of the first end 13 of the PCB 10 may comprise at least a first convex electrical contact surface 28a and the concave edge 23 of the second end 14 of the PCB 10 may comprise at least a first concave electrical contact surface 29a. In such a configuration, the at least first convex electrical contact surface 28a is configured to electrically connect with said at least first concave electrical contact surface 29a of said another LED module 100.

In a third type of configuration, the convex edge 21 of the first end 13 of the PCB 10 comprises a first convex electrical contact surface 28a and the concave edge 23 of the second end 14 of the PCB 10 comprises a first concave electrical contact surface 29a. In such a configuration, the first convex electrical contact surface 28a is configured to electrically connect with said first concave electrical contact surface 29a of said another LED module 100. Furthermore, the at least first connection strip 22a is an electrically conducting connection strip and the arc-shaped slot 24 comprises a first electrical contact surface 25a, the arc-shaped slot 24 being configured to receive said first electrically conducting connection strip 22a of said another LED module 100 such that said first electrical contact surface 25a connect with said first electrically conducting connection strip 22a.

The arc-shaped slot 24 may be a through-going slot in the PCB 10 and the LED module 100 may comprise a second connection strip 22b extending from the first end 13 of the PCB 10. In such a configuration, the first connection strip 22a is arranged on a front side 41 of the PCB 10 and the second connection strip 22b is arranged on a back side 42 of the PCB 10 and the arc-shaped slot 24 is configured to receive the second connection strip 22b of said another LED module 100. Moreover, in such a configuration the second connection strip 22b may be an electrically conducting connection strip, the arc-shaped slot 24 may comprise a second electrical contact surface 25b. The first and the second electrical contact surface 25a, 25b may be arranged, electrically isolated from each other, along the length of the arc-shaped slot 24 and at least on one inner side wall 27a, 27b of the arc-shaped slot 24. Then, the arc-shaped slot 24 may be configured to receive the first electrically conducting connection strip 22a and the second connection strip 22b such that the first and second electrical contact surfaces 25a, 25b connect with the first and the second electrically conducting connection strips 22a, 22b, respectively, of said another LED module 100. In this configuration, the inner side of the arc-shaped slot 24 may comprise a first inner side wall 27a opposite a second inner side wall 27b, wherein the first electrical contact surface 25a is arranged only on the first inner side wall 27a along the length of the arc-shaped slot 24, and the second electrical contact surface 25b is arranged only on the second inner side wall 27b along the length of the arc-shaped slot 24.

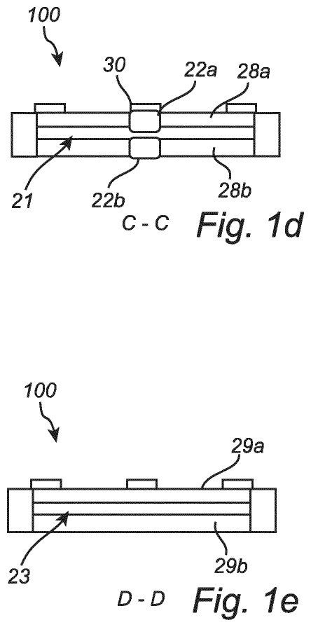

As illustrated in FIGS. 2a-d, an embodiment of a LED module 100 comprises a printed circuit board (PCB) 10 on which PCB 10 at least one LED 30 is arranged. The PCB 10 comprises a first mechanical and electrical interface 11 arranged at a first end 13 of the PCB 10 and a second mechanical and electrical interface 12 arranged at a second end 14 of the PCB 10. As exemplified in FIGS. 2a-d, the first end 13 of the PCB 10 and the second end 14 of the PCB 10 may be opposite ends of the PCB 10. However, other relationships may be realized where ends and interfaces of the PCB have other angular relationships.

The first mechanical and electrical interface 11 comprises a convex edge 21 of the first end 13 of the PCB 10 and the convex edge 21 has a first curvature radius.

The second mechanical and electrical interface 12 comprises, at the second end 14 of the PCB 10, a concave edge 23 that has the first curvature radius, i.e. the same curvature radius as the curvature radius of the convex edge 21 at the first end 13 of the PCB. The concave edge 23 is configured to receive a convex edge 21 of a first mechanical and electrical interface 11 of another LED module 100.

Further, in the embodiment illustrated in FIGS. 2a-d, the convex edge 21 of the first end 13 of the PCB 10 comprises a first convex electrical contact surface 42 and the concave edge 23 of the second end 14 of the PCB 10 comprises a first concave electrical contact surface 52. In this embodiment, the first convex electrical contact surface 42 is configured to electrically connect with the first concave electrical contact surface 52 of said another LED module 100.

The at least one LED 30 is arranged in electrical connection with the first mechanical and electrical interface 11 and in electrical connection with the second mechanical and electrical interface 12. Such electrical connections between the at least one LED 30 and the interfaces 11, 12 may be realized via connection paths on the surface of the PCB 10 as well as via paths within the PCB 10.

The convex edge 21 of the first end 13 of the PCB 10 may further comprise a second convex electrical contact surface 43 and the concave edge 23 of the second end 14 of the PCB 10 may further comprise a second concave electrical contact surface 53. In such a configuration, the second convex electrical contact surface 43 is configured to electrically connect with the second concave electrical contact surface 53 of said another LED module 100.

As illustrated in FIGS. 2a and 2b, the convex edge 21 of the first end 13 of the PCB 10 may comprise a cut-out slot 41. The cut-out slot 41 may have the shape as illustrated, however other shapes are possible, including V-shapes, U-shapes, rectangular shapes etc., all of which provides an effect of making the convex edge 21 of the PCB resilient in the plane of the PCB 10, which enables a secure mechanical connection, and thereby also a secure electrical contact, between the first mechanical and electrical interface 11 of the LED module 100 and the second mechanical and electrical interface 12 of said another LED module 100.

The cut-out slot 41 typically extends in a direction perpendicular to the convex edge 21, i.e. in a radial direction. As the convex edge 21 has a first curvature radius, the cut-out slot 41 preferably has a length of at least said first curvature radius and a width, or minimum width, of, e.g., at least 0.2 times said first curvature radius.

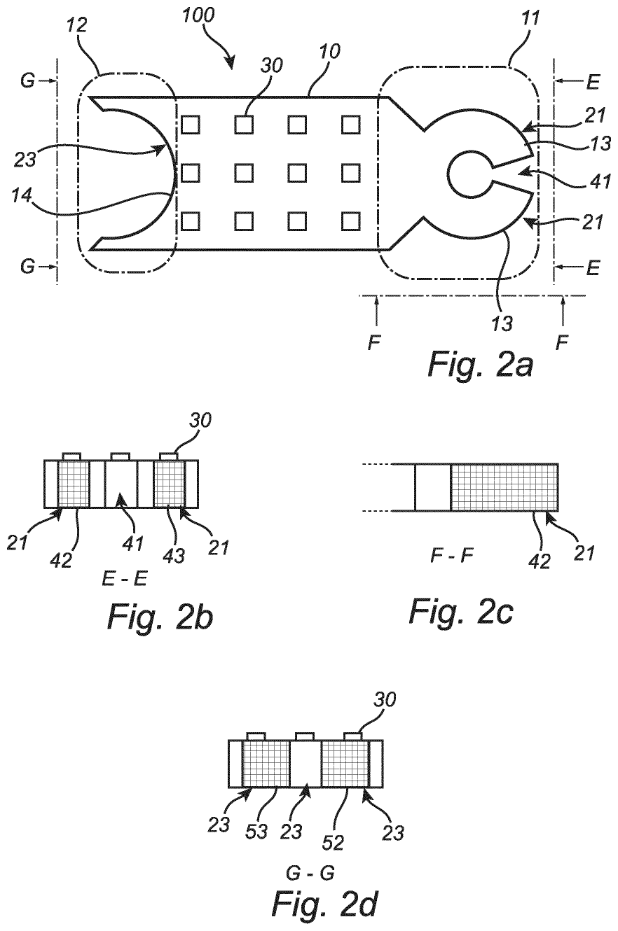

As illustrated in FIG. 3, and with continued reference to FIGS. 1a-e, a system 101 may comprise a plurality of LED modules 100.

Such a system may comprise three LED modules 100 configured as follows. A first mechanical and electrical interface 11 of a first LED module 100 may be connected with a second mechanical and electrical interface 12 of a second LED module 100 such that a convex edge 21 of the first mechanical and electrical interface 11 of the first LED module 100 abuts a concave edge 23 of the second mechanical and electrical interface 12 of the second LED module 100. In such a system at least a first connection strip 22a of the first mechanical and electrical interface 11 of the first LED module 100 is received in an arc-shaped slot 24 of the second mechanical and electrical interface 12 of the second LED module 100. Furthermore, a first mechanical and electrical interface 11 of a third LED module 100 may be connected with a second mechanical and electrical interface 12 of the first LED module 100 such that a convex edge 21 of the first mechanical and electrical interface 11 of the third LED module 100 abuts a concave edge 23 of the second mechanical and electrical interface 12 of the first LED module 100, and at least a first connection strip 22a of the first mechanical and electrical interface 11 of the third LED module 100 is received in an arc-shaped slot 24 of the second mechanical and electrical interface 12 of the first LED module 100.

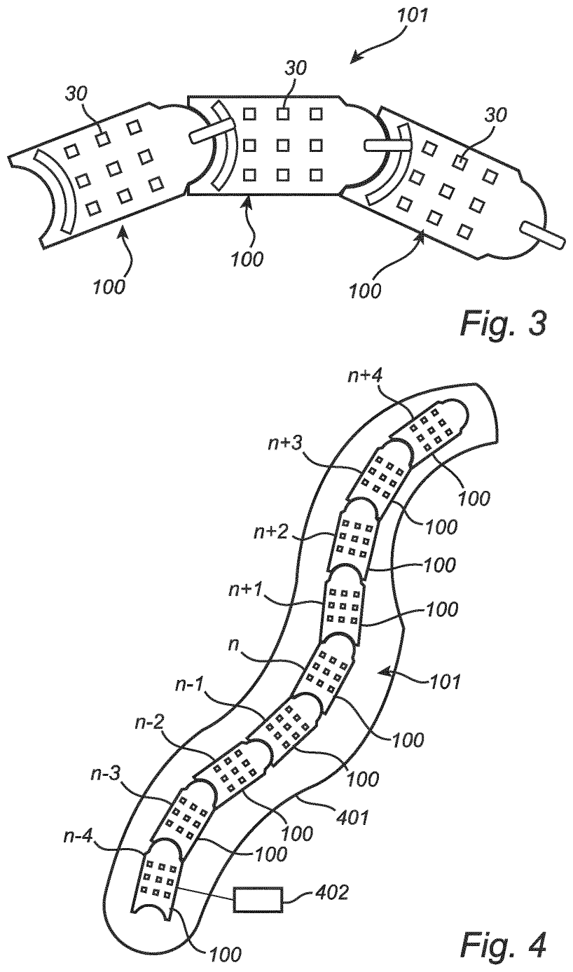

As illustrated in FIG. 4, and with continued reference to FIGS. 1a-e and FIGS. 2a-d, a system 101 may comprise an arbitrary number of LED modules 100 with or without connection strips in the first mechanical and electrical interface 11 and with or without an arc-shaped slot in the second mechanical and electrical interface 12. In the system 101, a first mechanical and electrical interface 11 of a LED module n 100 may be connected with a second mechanical and electrical interface 12 of a LED module n+1 100 such that a convex edge 21 of the first mechanical and electrical interface 11 of the LED module n 100 abuts a concave edge 23 of the second mechanical and electrical interface 12 of the LED module n+1 100. A second mechanical and electrical interface 12 of a LED module n 100 may be connected with a first mechanical and electrical interface 11 of the LED module n−1 100 such that a concave edge 23 of the second mechanical and electrical interface 12 of the LED module n 100 abuts a convex edge 21 of the first mechanical and electrical interface 11 of the LED module n−1 100.

FIG. 4 further illustrates a luminaire 401 comprising a system 101 of LED modules 100. Electric power is provided to the system 101 in the luminaire 401 from a power source 402.

1. A light emitting diode, LED, module comprising a printed circuit board, PCB on which PCB at least one LED is arranged, where:
the PCB comprises a first mechanical and electrical interface arranged at a first end of the PCB and a second mechanical and electrical interface arranged at a second end of the PCB,
the first mechanical and electrical interface comprises a convex edge of the first end of the PCB having a first curvature radius,
the second mechanical and electrical interface comprises, at the second end of the PCB, a concave edge having at most the first curvature radius, the concave edge being configured to receive a convex of a first mechanical and electrical interface of another LED module and
said at least one LED is arranged in electrical connection with the first mechanical and electrical interface and in electrical connection with the second mechanical and electrical interface,
wherein the first mechanical and electrical interface comprises at least a first connection strip extending from the first end of the PCB, and
the second mechanical and electrical interface comprises an arc-shaped slot in the PCB that is concentric with the concave edge of the second end of the PCB the arc-shaped slot having a curvature radius that is greater than the first curvature radius and configured to receive at least a first connection strip of said first mechanical and electrical interface of said another LED module.

2. The LED module of claim 1, where:
the first end of the PCB and the second end of the PCB are opposite ends of the PCB.

3. The LED module of claim 1, where:
the at least first connection strip comprises a resilient bulge fitting into the arc-shaped slot.

4. The LED module of claim 3, where the bulge is configured in the form of metal sheet material and shaped according to one of a flat bottom U shape, a U-shape, or an O-shape.

5. The LED module of claim 1, where:
the at least first connection strip is an electrically conducting connection strip,
the arc-shaped slot comprises at least a first electrical contact surface the arc-shaped slot being configured to receive said at least first electrically conducting connection strip of said another LED module such that said at least first electrical contact surface connect with said at least first electrically conducting connection strip.

6. The LED module of claim 1, where:
the convex edge of the first end of the PCB comprises at least a first convex electrical contact surface,
the concave edge of the second end of the PCB comprises at least a first concave electrical contact surface, where
said at least first convex electrical contact surface being configured to electrically connect with said at least first concave electrical contact surface of said another LED module.

7. The LED module of claim 1 where:
the convex edge of the first end of the PCB comprises a first convex electrical contact surface,
the concave edge of the second end of the PCB comprises a first concave electrical contact surface,
said first convex electrical contact surface being configured to electrically connect with said first concave electrical contact surface of said another LED module,
the at least first connection strip is an electrically conducting connection strip,
the arc-shaped slot comprises a first electrical contact surface, the arc-shaped slot being configured to receive said first electrically conducting connection strip of said another LED module such that said first electrical contact surface connect with said first electrically conducting connection strip.

8. The LED module of claim 1, where the arc-shaped slot is a through-going slot in the PCB and comprising:
a second connection strip extending from the first end of the PCB, and where:
the first connection strip is arranged on a front side of the PCB and the second connection strip is arranged on a back side of the PCB
the arc-shaped slot is configured to receive the second connection strip of said another LED module

9. The LED module of claim 8, where:
the second connection strip is an electrically conducting connection strip,
the arc-shaped slot comprises a second electrical contact surface,
the first and the second electrical contact surface are arranged, electrically isolated from each other, along the length of the arc-shaped slot and at least on one inner side wall of the arc-shaped slot,
the arc-shaped slot being configured to receive the first electrically conducting connection strip and the second connection strip such that the first and second electrical contact surfaces connect with the first and the second electrically conducting connection strips respectively, of said another LED module.

10. The LED module of claim 9, wherein the inner side of the arc-shaped slot comprises a first inner side wall opposite a second inner side wall, wherein the first electrical contact surface is arranged only on the first inner side wall, along the length of the arc-shaped slot and the second electrical contact surface is arranged only on the second inner side wall along the length of the arc-shaped slot.

11. A system comprising a plurality of LED modules according to claim 1.

12. A luminaire comprising a system of LED modules according to claim 11.
